(19) United States
(12) Patent Application Publication
(10) Pub. No.: US 2013/0002355 A1
(43) Pub. Date: Jan. 3, 2013

(54) DIFFERENTIAL AMPLIFIER AND COMPARATOR

(75) Inventors: Shuuji TODA, Kanagawa-ken (JP); Mamoru MIWA, Kanagawa-ken (JP)

(73) Assignee: KABUSHIKI KAISHA TOSHIBA, Tokyo (JP)

(21) Appl. No.: 13/420,671

(22) Filed: Mar. 15, 2012

(30) Foreign Application Priority Data
Jun. 29, 2011 (JP) 2011-143759

(51) Int. Cl. H03F 3/45

(52) U.S. Cl. 330/257

(57) ABSTRACT

According to one embodiment, a differential amplifier includes a differential circuit, an output circuit, and a clipper circuit. The differential circuit generates a pair of differential currents in accordance with a difference in potential between a pair of input signals. The output circuit receives the pair of differential currents and generates an output voltage in accordance with the current difference. The clipper circuit suppresses the output voltage within a range to be able to convert to a low level or to a high level being higher than the low level.

### CROSS-REFERENCE TO RELATED APPLICATIONS

This application is based upon and claims the benefit of priority from the prior Japanese Patent Application No. 2011-143759, filed on Jun. 29, 2011; the entire contents of which are incorporated herein by reference.

### FIELD

Embodiments described herein relate generally to a differential amplifier and a comparator.

### BACKGROUND

A differential amplifier that amplifies a differential signal is used as a basic circuit for various types of electronic circuits. For example, in the early stages of operational amplifiers and comparators, a differential amplifier is used to amplify a weak signal. An input offset in the differential amplifier in operational amplifiers causes an error in the output signal. Further, in comparators, the error in the output signal occurring as a result of the input offset causes an error in the threshold voltage between a low level and a high-level being higher than the low level. Accordingly, variation in the input offset of a comparator results in variation in the threshold voltage.

### BRIEF DESCRIPTION OF THE DRAWINGS

FIG. 1 is a circuit diagram illustrating a configuration of a differential amplifier according to a first embodiment;

FIG. 2 is another circuit diagram illustrating a configuration of a differential amplifier according to the first embodiment;

FIG. 3 is a circuit diagram illustrating a configuration of a differential amplifier according to a second embodiment;

FIG. 4 is another circuit diagram illustrating a configuration of a differential amplifier according to the second embodiment;

FIG. 5 is a circuit diagram illustrating a configuration of a comparator according to a third embodiment;

FIG. 6 is a block diagram to measure characteristics of a comparator;

FIG. 7 is a characteristic diagram illustrating characteristics of a comparator according to the third embodiment; and

FIG. 8 is a characteristic diagram of a comparative example of a comparator.

### DETAILED DESCRIPTION

In general, according to one embodiment, a differential amplifier includes a differential circuit, an output circuit, and a clipper circuit. The differential circuit generates a pair of differential currents in accordance with a difference in potential between a pair of input signals. The output circuit receives the pair of differential currents and generates an output voltage in accordance with the current difference. The clipper circuit suppresses the output voltage within a range to be able to convert to a low level or to a high level being higher than the low level.

Hereinbelow, embodiments are described with reference to the drawings. In the following description, identical components are marked with the same reference numerals, and a description of components once described is omitted as appropriate. The embodiments described below can be appropriately combined.

First, a description of a first embodiment will be given.

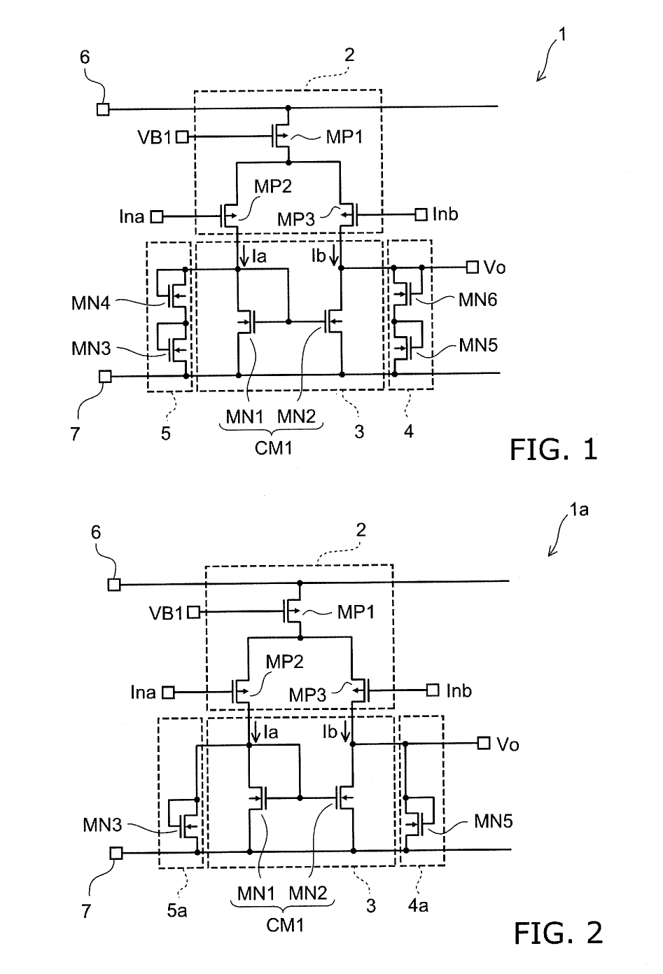

FIG. 1 is a circuit diagram illustrating a configuration of a differential amplifier according to the first embodiment.

In a differential amplifier 1, a differential circuit (portion enclosed by the broken line 2) and an output circuit (portion enclosed by the broken line 3) are connected in series between a first power terminal 6 and a second power terminal 7. Further, a pair of clipper circuits 4 and 5 is connected in parallel to an output circuit 3.

A differential circuit 2 has a differential pair configured with a pair of P channel type MOSFET (hereinafter referred to as PMOS) MP2 and MP3. Each source for the PMOS MP2 and MP3 are mutually connected and are connected to the first power terminal 6 through the PMOS MP1. A bias voltage VB1 is supplied to the PMOS MP1 gate. With the PMOS MP1, a power source potential Vdd is supplied through the first power terminal 6 to supply a constant current to each source of PMOS MP2 and MP3. Respective input signals Ina and Inb are input into each gate of PMOS MP2 and MP3. A pair of differential currents Ia and Ib are generated according to the potential of the input signals Ina and Inb for each drain of PMOS MP2 and MP3. Further, the structure and characteristics such as the oxide film thickness and size including the threshold voltage, gate width, gate length and the like of the PMOS MP2 and MP3 configuring the differential pair are the same and exemplify parity.

The output circuit 3 has a current mirror circuit CM1 configured with a pair of N channel type MOSFET (hereinafter referred to as NMOS) MN1 and MN2. The NMOS MN1 is connected to a diode between the drain of the PMOS MN2 and the second power terminal 7. The gate and drain of the NMOS MN1 is connected to the drain of the PMOS MP2, and the source of the NMOS MN1 is connected to the second power terminal 7. NMOS MN1 is on the reference side of the current mirror circuit CM1, and differential current Ia flows to the drain of the NMOS MN1. The drain of the NMOS MN2 is connected to the drain of the PMOS MP3, and the source is connected to the second power terminal 7, and the gate is connected to the gate and drain of the NMOS MN1. NMOS MN2 is on the output side of the current mirror circuit CM1, and differential current Ib flows to the drain of the NMOS MN2. NMOS MN1 and MN2 receive the pair of differential currents Ia and Ib respectively, and an output voltage Vo according to the current difference is generated between the drain and source of the NMOS MN2. Note that structure and characteristics such as the threshold voltage, size, and oxide film thickness of the NMOS MN1 and MN2 configuring the current mirror circuit CM1 are the same and exemplify parity.

The clipper circuit 4, having clipper elements MN5 and MN6 connected in series, is connected in parallel to the NMOS MN2 of the output circuit 3. The clipper elements MN5 and MN6 switch ON according to the output voltage Vo, and the voltages at both ends of the clipper elements MN5 and MN6 are held to the respective threshold voltages Vth. Therefore, the clipper circuit 4 holds the output voltage Vo to near the value 2×Vth of the combined threshold voltages Vth of the clipper elements MN5 and MN6. Note that the clipper elements MN5 and MN6 are respectively configured with a diode-connected NMOS.

The clipper circuit 5, having clipper elements MN3 and MN4 connected in series, is connected in parallel to the NMOS MN1 of the output circuit 3. The clipper elements MN3 and MN4 switch ON according to the drain to source voltage of NMOS MN1, and the drain to source voltage of NMOS MN1 is held to near the value 2×Vth of the combined threshold voltages Vth of the clipper elements MN3 and MN4. The clipper circuit 5 maintains the parity of the output circuit 3. Note that the clipper elements MN3 and MN4 are respectively configured with a diode-connected NMOS.

According to the description given above, the differential amplifier 1 has the same structure and characteristics such as threshold voltage, size, and oxide film thickness of the element that configures the differential circuit 2, output circuit 3, and clipper circuits 4 and 5, and exhibits parity. Therefore, when the potential of the input signals Ina and Inb are equal, the voltages generated to NMOS MN1 and MN2 of the output circuit 3 are equal, and the offset voltage is 0.

However, when the potential of the input signal Ina is higher than the potential of the input signal Inb, the differential current Ib of the PMOS MP3 side becomes greater than the differential current Ia of the PMOS MP2 side, and the drain potential of NMOS MN2 approaches the power source potential Vdd supplied to the first power terminal 6. Meanwhile, because the NMOS MN1 is connected to diodes that are connected to the gate and drain, the drain potential of the NMOS MN1 is fixed to be near the threshold voltage Vth of the NMOS MN1. Therefore, the source to drain voltage (the reverse polarity voltage to the drain to source voltage) of the PMOS MP2 of the differential circuit 2 is higher than the source to drain voltage of the PMOS MP3.

Note that, here, the effects of the channel length modulation effect are ignored.

However, with MOSFET, drive capability changes with fluctuations in the threshold voltage due to drain avalanche hot-carrier (DAHC) as the absolute value of the voltage applied across the drain to source increases. For example, when operating NMOS in a saturation region, the positive gate potential is enhanced on account of the hot hole injected into the gate oxide film by collision ionization, and thus the drive capability is raised.

Accordingly, when the source to drain voltage of the PMOS MP2 is higher than the source to drain voltage of the PMOS MP3, parity is lost and the offset voltage increases. Further, the higher the difference in the potentials between the first power terminal 6 and the second power terminal 7, the greater the variance in the offset voltage.

Therefore, in the differential amplifier 1, the clipper circuit 4 is connected in parallel to the NMOS MN2 of the output circuit 3 and holds the output voltage Vo to about near 2×Vth. When the potential of the input signal Ina is higher than the potential of the input signal Inb and the output voltage Vo is no less than 2×Vth, current will flow in the route of the clipper elements MN5 and MN6. Because the clipper elements MN5 and MN6 are respectively configured with diode-connected NMOS, the voltage at both ends are respectively held to the threshold voltage Vth. Therefore, the output voltage Vo is held to about 2×Vth without reaching a voltage value higher than 2×Vth.

Accordingly, the difference in the potentials between the drain potential of NMOS MN1 and the drain potential of NMOS MN2 of the output circuit 3 is held to no more than 2×Vth. Further, the difference in voltages between the source to drain voltage of the PMOS MP2 and the source to drain voltage of the PMOS MP3 of the differential circuit 2 is also held to no more than 2×Vth.

Further, even if the difference in the potentials between the potential of the first power terminal 6 and the potential of the second power terminal 7 increases, the potential difference and voltage difference described above will be held to no more than 2×Vth thereby reducing the variance in the offset voltage.

Further, because the output voltage Vo is suppressed by the clipper circuit 4, the propagation delay time for when the output voltage Vo according to the input signals Ina and Inb is lowered from a high level to a low level becomes shorter compared to when it is not suppressed.

Note that, as described above, the clipper circuit 5 has the same configuration as the clipper circuit 4 and is connected to the NMOS MN1 side in order to maintain the parity of the output circuit 3.

Further, the output circuit 3 includes a current mirror circuit CM1 having an active load with a high impedance to the differential circuit 2. Thus, the differential amplifier 1 can obtain a high gain in one step.

FIG. 2 is another circuit diagram illustrating a configuration of a differential amplifier according to the first embodiment.

Note that, in FIG. 2, the same reference numerals are attached to elements that are the same in FIG. 1.

According to the illustration given in FIG. 2, a differential amplifier 1a is configured by replacing the clipper circuits 4 and 5 of the differential amplifier 1 illustrated in FIG. 1 with clipper circuits 4a and 5a. Differential circuit 2 and output circuit 3 are similar to that given in FIG. 1.

The clipper circuit 4a has a clipper element MN5 connected in parallel to the NMOS MN2 of the output circuit 3. The clipper element MN5 holds the output voltage Vo to near the threshold voltage VthH of the clipper element MN5. Note that the clipper element MN5 is configured with a diode-connected NMOS.

Further, a clipper circuit 5a has a clipper element MN3 connected in parallel to the NMOS MN1 of the output circuit 3. The clipper element MN3 holds the drain to source voltage of the NMOS MN1 to near the threshold voltage VthH of the clipper element MN3. The clipper circuit 5a maintains the parity of the output circuit 3. Note that the clipper element MN3 is configured with a diode-connected NMOS.

Setting the threshold voltage VthH of the clipper elements MN5 and MN3 to be higher than the threshold voltage Vth of the NMOS MN1 and MN2 operates the amplifier normally.

Accordingly, the difference in the potentials between the drain potential of NMOS MN2 and the drain potential of NMOS MN1 of the output circuit 3 is held to no more than VthH. Further, the difference in voltages between the source to drain voltage of the PMOS MP2 and the source to drain voltage of the PMOS MP3 of the differential circuit 2 is also held to no more than VthH.

Even if the difference in the potentials between the potential of the first power terminal 6 and the potential of the second power terminal 7 increases, the potential difference and voltage difference described above will not be a voltage of greater than the threshold voltage VthH thereby reducing the variance in the offset voltage.

Further, because the output voltage Vo is suppressed, the propagation delay time for when the output voltage Vo according to the input signals Ina and Inb is lowered from a high level to a low level becomes shorter compared to when it is not suppressed.

Next a second embodiment will be described.

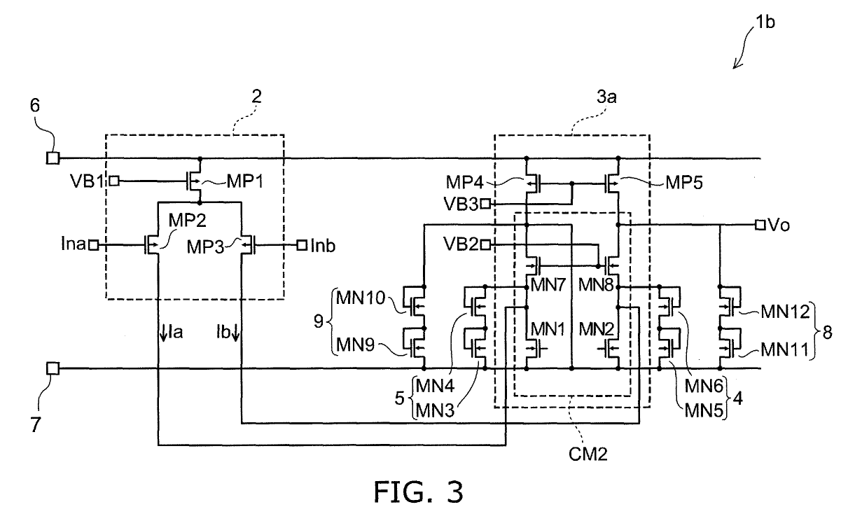

FIG. 3 is a circuit diagram illustrating a configuration of a differential amplifier according to the second embodiment.

In FIG. 3, an example is illustrated of a configuration of a cascode coupling in a folded form. Note that, in FIG. 3, the same reference numerals are attached to elements that are the same in FIG. 1.

A differential amplifier 1b is configured by replacing the output circuit 3 of the differential amplifier 1 illustrated in FIG. 1 with an output circuit 3a and adding clipper circuits 8 and 9. The differential circuit 2 is similar to that given in FIG. 1.

The output circuit 3a is connected between the first power terminal 6 and the second power terminal 7. A pair of PMOS MP4 and MP5 is connected between the first power terminal 6 and the second power terminal 7 via a current mirror circuit CM2. Each source of the PMOS MP4 and MP5 is connected to the first power terminal 6. A bias voltage VB3 is supplied to each gate of the PMOS MP4 and MP5. The PMOS MP4 and MP5 supply constant current to the current mirror CM2. The current mirror circuit CM2 is cascode coupling by NMOS MN7 and MN8 respectively to the pair of NMOS MN1 and MN2. A bias voltage VB2 is supplied to the NMOS MN7 gate. The NMOS MN1 is connected between PMOS MP4 and the second power terminal 7 via NMOS MN7 of the gate ground. Further, a bias voltage VB2 is supplied to the NMOS MN8 gate. The NMOS MN2 is connected between PMOS MP5 and the second power terminal 7 via NMOS MN8 of the gate ground. Because NMOS MN8 is cascode coupling to the NMOS MN2, current mirror circuit CM2 has a high output impedance. Further, because NMOS MN7 is cascode coupling to the NMOS MN1, the drain to source voltage of NMOS MN1 is equivalent to the drain to source voltage of NMOS MN2. The drain of NMOS MN1 is connected to the drain of PMOS MP2 of the differential circuit 2, and differential current Ia flows to NMOS MN1. NMOS MN1 and MN7 are the references side. The drain of NMOS MN2 is connected to the drain of PMOS MP3 of the differential circuit 2, and differential current Ib flows to NMOS MN2. NMOS MN2 and MN8 are the output side, and an output voltage Vo is generated between the drain of NMOS MN8 and the source of NMOS MN2.

The clipper circuit 4, having clipper elements MN5 and MN6 connected in series, is connected in parallel to the NMOS MN2 of the output circuit 3a. The clipper elements MN5 and MN6 hold the drain to source voltage of the NMOS MN2 to near the value 2×Vth of the combined threshold voltages Vth of the clipper elements MN5 and MN6. Note that the clipper elements MN5 and MN6 are respectively configured with NMOS.

The clipper circuit 5, having clipper elements MN3 and MN4 connected in series, is connected in parallel to the NMOS MN1 of the output circuit 3a. The clipper elements MN3 and MN4 hold the drain to source voltage of the NMOS MN1 to near the value 2×Vth of the combined threshold voltages Vth of the clipper elements MN3 and MN4.

The clipper circuit 8, having clipper elements MN11 and MN12 connected in series, is connected in parallel to the cascode coupling NMOS MN8 and MN2. The clipper elements MN 11 and MN12 hold the output voltage Vo to near the value 2×Vth of the combined threshold voltages Vth of the clipper elements MN 11 and MN12.

The clipper circuit 9, having clipper elements MN9 and MN10 connected in series, is connected in parallel to the cascode coupling NMOS MN1 and MN7. The clipper elements MN9 and MN10 hold the voltage between the drain of NMOS MN7 and the source of NMOS MN1 to near the value 2×Vth of the combined threshold voltages Vth of the clipper elements MN9 and MN10. The clipper circuits 5 and 9 maintain the parity of the output circuit 3a.

Note that each clipper element is configured with an enhanced NMOS connected to a diode, and the threshold voltages of each NMOS are all the equivalent at Vth.

Even in the differential amplifier 1b, the difference in the potentials between the drain potential of NMOS MN1 and the drain potential of NMOS MN2 of the output circuit 3a is held to no more than 2×Vth. The difference in voltages between the drain to source voltage of the PMOS MP4 and the drain to source voltage of the PMOS MP5 is also held to no more than 2×Vth. Further, the difference in voltages between the source to drain voltage of the PMOS MP2 and the source to drain voltage of the PMOS MP3 of the differential circuit 2 is also held to no more than 2×Vth.

Therefore, even if the difference in the potentials between the potential of the first power terminal 6 and the potential of the second power terminal 7 increases, the potential difference and voltage difference described above will be held to no more than 2×Vth thereby reducing the variance in the offset voltage.

Further, because the output voltage Vo is suppressed by the clipper circuits 4 and 8, the propagation delay time for when the output voltage Vo according to the input signals Ina and Inb is lowered from a high level to a low level becomes shorter compared to when it is not suppressed.

Further, because the differential amplifier 1b has the output circuit 3a cascode coupling to the differential circuit 2, the range of the common mode input voltage of the differential circuit 2 can be broadened. In other words, the range of the common mode input voltage of the input signals Ina and Inb can be broadened to the potential side of the second power terminal 7. Further, because the output circuit 3a has a cascode coupling current mirror circuit CM2, the impedance can be higher than in the current mirror circuit CM1, and the differential amplifier 1b can obtain an even higher gain.

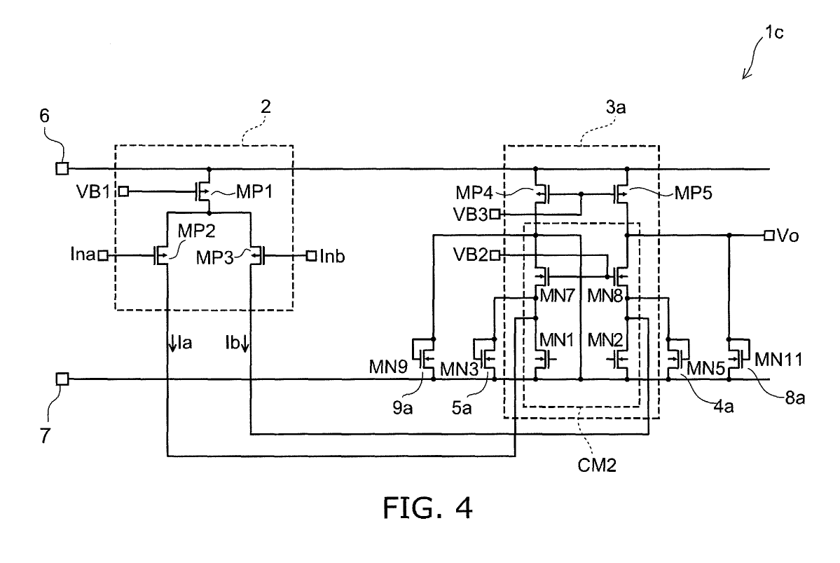

FIG. 4 is another circuit diagram illustrating a configuration of a differential amplifier according to the second embodiment.

Note that, in FIG. 4, the same reference numerals are attached to elements that are the same in FIG. 3.

According to the illustration given in FIG. 4, a differential amplifier 1c is configured by replacing the clipper circuits 4, 5, 8 and 9 of the differential amplifier 1b illustrated in FIG. 3 with clipper circuits 4a, 5a, 8a and 9a.

The clipper circuit 4a has a clipper element MN5 connected in parallel to the NMOS MN2 of the output circuit 3a. The clipper element MN5 holds the drain to source voltage of the NMOS MN2 to near the threshold voltage VthH of the clipper element MN5.

The clipper circuit 5a has a clipper element MN3 connected in parallel to the NMOS MN1 of the output circuit 3a. The clipper element MN3 holds the drain to source voltage of the NMOS MN1 to near the threshold voltage VthH of the clipper element MN3. The clipper circuit 5a maintains the parity of the output circuit 3a.

A clipper circuit 8a has a clipper element MN11 connected in parallel to the cascode coupling NMOS MN2 and MN8 of the output circuit 3a. The clipper element MN11 holds the output voltage Vo to near the threshold voltage VthH of the clipper element MN11.

A clipper circuit 9a has a clipper element MN9 connected in parallel to the cascode coupling NMOS MN1 and MN7 of the output circuit 3a. The clipper element MN9 holds the voltage between the drain of the NMOS MN7 and the source MN1 to near the threshold voltage VthH of the clipper element MN9. The clipper circuits 5a and 9a maintain the parity of the output circuit 3a.

Each clipper element is configured with a diode-connected NMOS, and setting each clipper threshold voltage VthH of to be higher than the threshold voltage Vth of NMOS MN1, MN2, MN7, and MN8 operates the amplifier normally.

Even in the differential amplifier 1c, the difference in the potentials between the drain potential of NMOS MN2 and the drain potential of NMOS MN1 of the output circuit 3a is held to no more than VthH. The difference in voltages between the drain to source voltage of the PMOS MP5 and the drain to source voltage of the PMOS MP4 is also held to no more than VthH. Further, the difference in voltages between the source to drain voltage of the PMOS MP2 and the source to drain voltage of the PMOS MP3 of the differential circuit 2 is also held to no more than VthH.

Therefore, even if the difference in the potentials between the potential of the first power terminal 6 and the potential of the second power terminal 7 increases, the potential difference and voltage difference described above will be held to no more than VthH thereby reducing the variance in the offset voltage.

Further, because the output voltage Vo is suppressed by the clipper circuits 4 and 8, the propagation delay time for when the output voltage Vo according to the input signals Ina and Inb is lowered from a high level to a low level becomes shorter compared to when it is not suppressed.

Next, a third embodiment will be explained.

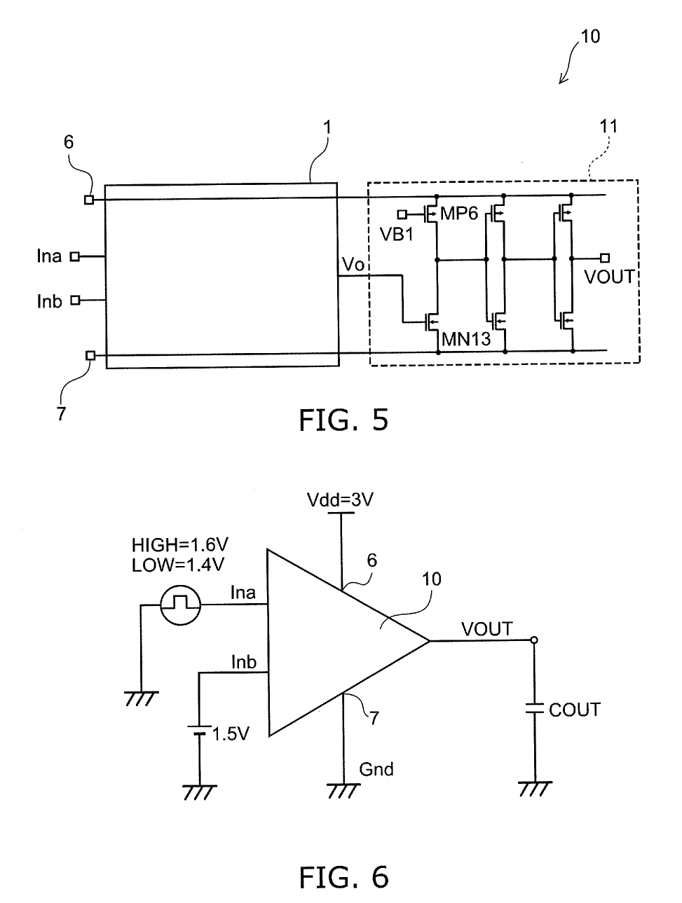

FIG. 5 is a circuit diagram illustrating a configuration of a comparator according to a third embodiment.

In FIG. 5, an example is illustrated of the comparator 10 in which the differential amplifier 1 is used. Note that, in FIG. 5, the same reference numerals are attached to elements that are the same in FIG. 1.

The comparator 10 is provided with the differential amplifier 1 that amplifies the potential difference in input signals Ina and Inb, and with a converter circuit 11 that converts output voltage Vo of the amplifier 1 to a low level or a high level that is higher than the low level, and outputs as output voltage VOUT.

The differential amplifier 1 is the same as the differential amplifier 1 illustrated in FIG. 1.

The converter circuit 11 includes a PMOS MP6 and an NMOS MN13 that are connected in a series between the first power terminal 6 in the second power terminal 7. A bias voltage VB1 is supplied to the PMOS MP6 gate, and the PMOS MP6 supplies constant current to the NMOS MN13. The PMOS MP6 operates as a load circuit of NMOS MN13. Output voltage Vo of the differential amplifier 1 is input into the NMOS MN13 gate. Output voltage is generated to the MNOS MN13 drain. The output voltage of the MNOS MN13 is output as output voltage through a buffer configured with a two-step CMOS inverter.

When the output voltage Vo of the differential amplifier 1 is lower than the threshold voltage Vth of the NMOS MN13, the output voltage VOUT is at a high level. When the output voltage Vo is higher than the threshold voltage Vth of the NMOS MN13, the output voltage VOUT is at a low level.

In the comparator 10, variance in the offset voltage of the differential amplifier 1 is reduced. Therefore, even if the difference in the potentials of the potential of the first power terminal 6 and the potential of the second power terminal 7 increases, variance in the voltage of the change point between the low level and a high level of the output voltage VOUT is reduced.

Further, because the output voltage Vo is suppressed by the clipper circuits 4 and 8, the propagation delay time for when the output voltage Vo according to the input signals Ina and Inb is lowered from a high level to a low level becomes shorter compared to when it is not suppressed.

FIG. 6 is a block diagram to measure characteristics of a comparator.

The second power terminal 7 of the comparator 10 is grounded, and in the power source potential Vdd=3 V is supplied to the first power terminal 6. A rectangular wave is input as the input signal Ina with the high level at 1.6 V and the low level at 1.4 V, and a potential of 1.5 V is input as the input signal Inb. Further, a condenser COUT=1 μF is connected to the output as the load. The voltage at both ends of the condenser COUT becomes the output voltage VOUT.

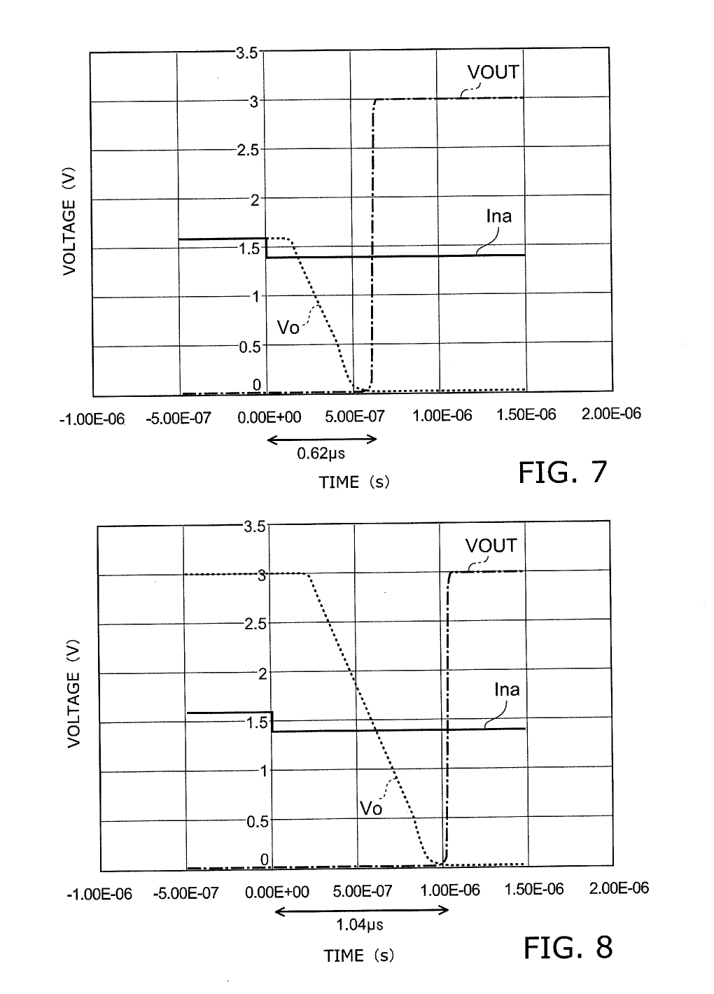

FIG. 7 is a characteristic diagram illustrating characteristics of a comparator according to the third embodiment.

The input signal Ina drops from the high level 1.6 V to the low-level 1.4 V in the time 0 s. The output voltage Vo of the differential amplifier 1 drops from 1.58 V to 0 V, and the output voltage VOUT of the comparator 10 rises from 0 V to 3 V.

The propagation delay time for when the output voltage VOUT of the comparator 10 rises from the low level to the high-level is about 0.62 μs.

FIG. 8 is a characteristic diagram of a comparative example of a comparator.

The input signal Ina drops from the high level 1.6 V to the low-level 1.4 V in the time 0 s. The output voltage Vo of the differential amplifier 1 drops from 3 V to 0 V, and the output voltage VOUT of the comparator 10 rises from 0 V to 3 V.

The propagation delay time for when the output voltage VOUT of the comparator 10 rises from the low level to the high-level is about 1.04 μs.

In this manner, in the comparator 10 in which the differential amplifier 1 is used, because the output voltage Vo is suppressed, the propagation delay time for when the output voltage Vo according to the input signals Ina and Inb is lowered from a high level to a low level is shortened compared to when it is not suppressed.

Note that although an example was illustrated of a configuration in which the differential circuit is a PMOS, the output circuit is an NMOS, and the converter circuit is an NMOS respectively, configurations are also possible in which the PMOS and NMOS are respectively switched.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A differential amplifier comprising:
a differential circuit generating a pair of differential currents in accordance with a difference in potential between a pair of input signals;
an output circuit receiving the pair of differential currents and generating an output voltage in accordance with the current difference; and
a clipper circuit suppressing the output voltage within a range to be able to convert to a low level or to a high level being higher than the low level.

2. The amplifier according to claim 1, wherein the differential circuit includes a pair of transistors configured to have an identical structure and identical characteristics.

3. The amplifier according to claim 1, wherein constant current is supplied to the differential circuit.

4. The amplifier according to claim 1, wherein the clipper circuit includes a diode-connected N-channel type MOSFET.

5. The amplifier according to claim 1, wherein the output circuit includes a current mirror circuit.

6. The amplifier according to claim 5, wherein
the clipper circuit includes a clipper element and a threshold voltage of the clipper element is higher than a threshold voltage of the current mirror circuit.

7. The amplifier according to claim 5, wherein
the clipper circuit includes a clipper element and a threshold voltage of the clipper element is equivalent to the threshold voltage of the current mirror circuit.

8. The amplifier according to claim 1, wherein the output circuit is cascode coupling to the differential circuit.

9. The amplifier according to claim 1, wherein the output circuit includes a plurality of current mirror circuits that are cascode coupling.

10. The amplifier according to claim 9, wherein another clipper circuit with an identical configuration to the clipper circuit is connected to at least one of the plurality of current mirror circuits.

11. A comparator comprising:
a differential amplifier including:
a differential circuit generating a pair of differential currents in accordance with a difference in potential between a pair of input signals;
an output circuit receiving the pair of differential currents and generating an output voltage in accordance with the current difference; and
a clipper circuit suppressing the output voltage within a range to be able to convert to a low level or to a high level being higher than the low level, and
a converter circuit that converts output voltage of the differential amplifier to the low level or the high level.

12. The comparator according to claim 11, wherein the differential circuit includes a pair of transistors configured to have an identical structure and identical characteristics.

13. The comparator according to claim 11, wherein constant current is supplied to the differential circuit.

14. The comparator according to claim 11, wherein the clipper circuit includes a diode-connected N-channel type MOSFET.

15. The comparator according to claim 11, wherein the output circuit includes a current mirror circuit.

16. The comparator according to claim 15, wherein
the clipper circuit includes a clipper element and a threshold voltage of the clipper element is higher than a threshold voltage of the current mirror circuit.

17. The comparator according to claim 15, wherein
the clipper circuit includes a clipper element and a threshold voltage of the clipper element is equivalent to the threshold voltage of the current mirror circuit.

18. The comparator according to claim 11, wherein the output circuit is cascode coupling to the differential circuit.

19. The comparator according to claim 11, wherein the output circuit includes a plurality of current mirror circuits that are cascode coupling.

20. The comparator according to claim 19, wherein another clipper circuit with an identical configuration to the clipper circuit is connected to at least one of the plurality of current mirror circuits.
